(19) United States
(12) Patent Application Publication
(10) Pub. No.: US 2026/0169038 A1
(43) Pub. Date: Jun. 18, 2026

(54) APPARATUS, SYSTEM AND METHOD FOR MEASURING HIGH VOLTAGE ON HIGH-VOLTAGE NODE

(71) Applicant: Hitachi Energy Ltd, Zürich (CH)

(72) Inventors: Weichi ZHANG, Beijing (CN); XiaoBo YANG, Beijing (CN); XiaoBing DONG, Beijing (CN)

(21) Appl. No.: 18/710,569

(22) PCT Filed: Nov. 16, 2021
(86) PCT No.: PCT/EP2021/081875

§ 371 Date: May 15, 2024

(51) Int. Cl. G01R 19/22; G01R 15/06; G01R 19/02; G01R 19/04; G01R 25/00

(52) U.S. Cl. CPC G01R 19/22; G01R 15/06; G01R 19/02; G01R 19/04; G01R 25/00

(57) ABSTRACT

An apparatus including a first AC-to-DC converter, a first DC-to-AC converter and a second AC-to-DC converter, the first AC-to-DC converter connected with a low voltage arm of a high voltage divider to obtain a voltage measurement signal, the first DC-to-AC converter configured to output a modulated signal of the voltage measurement signal, the second AC-to-DC converter configured to output a demodulated signal of the voltage measurement signal; a high-frequency transformer including a primary coil connected with an output terminal end of the first DC-to-AC converter and a secondary coil connected with an input terminal of the second AC-to-DC converter; and a controller configured to control switching devices of the first DC-to-AC converter to control a turn-on sequence of each switching device, to calculate signal parameters, and to output the calculated signal parameters.

### CROSS REFERENCE TO RELATED APPLICATIONS

This application is a 35 U.S.C. § 371 national stage application of PCT International Application No. PCT/EP2021/081875 filed on Nov. 16, 2021, the disclosure and content of which is incorporated by reference herein in its entirety.

### TECHNICAL FIELD

The present disclosure relates to a solution for measuring a high voltage on a high-voltage node.

### BACKGROUND

A capacitor voltage transformer (CVT) is widely used in high-voltage applications. A conventional CVT found in the prior art typically includes a capacitor voltage divider (CVD) and an electromagnetic unit (EMU). According to the operating principle of the conventional CVT, a high voltage on the high voltage node is firstly stepped down by the CVD and then fed to an intermediate voltage transformer (IVT) of the EMU to be further stepped down to a low voltage, which will be provided to meters or protective relays connected at user equipment side. However, such a conventional CVT includes several challenges. Since the CVT includes energy storage components (e.g., capacitors and inductors) that are designed to resonate at a fundamental frequency (e.g., 50 Hz/60 Hz) during a normal operation, the measuring accuracy for measuring the high voltage can be only guaranteed at the fundamental frequency and harmonic detection cannot be realized. In addition, a damping reactor is required to be connected in parallel on secondary residual windings of the EMU to attenuate Ferro-resonance, a tap voltage from the CVD should be above 10 kV, and otherwise the resonance energy cannot be damped out. In this manner, to output a low voltage of about 100V, a large magnetic core with high turns-ratio must be used in the IVT, which increases the cost and volume of the CVT, and a high insulation level of the IVT is required to comply with requirements of the high tap voltage from the CVD.

### SUMMARY

This Summary is provided to introduce a group of concepts that are further described below in the Detailed Description. It is not intended to identify key features or essential features of the claimed subject matter, nor is it intended to be used to limit the scope of the claimed subject matter.

In view of the above problems in the prior art, the present disclosure provides in one aspect an apparatus for measuring a high voltage on a high-voltage node including: a power electronic converter comprising a first AC-to-DC converter, a first DC-to-AC converter and a second AC-to-DC converter, the first AC-to-DC converter being connected with a low voltage arm of a high voltage divider, which is coupled between the HV node and the apparatus, to obtain a voltage measurement signal, the first DC-to-AC converter being configured to output a modulated signal of the voltage measurement signal, the second AC-to-DC converter being configured to output a demodulated signal of the voltage measurement signal; a high-frequency transformer comprising a primary coil connected with an output terminal of the first DC-to-AC converter to receive the modulated signal and a secondary coil connected with an input terminal of the second AC-to-DC converter; and a controller configured to provide control signals to control switching devices of the first DC-to-AC converter to control a turn-on sequence of each switching device such that the first DC-to-AC converter outputs the modulated signal, to calculate signal parameters including phase information and amplitude information of the high voltage on the high-voltage node, and to output the calculated signal parameters.

The present disclosure provides in another aspect a system for measuring a high voltage on a high-voltage node including a high voltage divider connected with the HV node; and a measuring apparatus provided in a terminal box coupled with the high voltage divider, the measuring apparatus including: a power electronic converter comprising a first AC-to-DC converter, a first DC-to-AC converter and a second AC-to-DC converter, the first AC-to-DC converter being connected with a low voltage arm of the high voltage divider to obtain a voltage measurement signal, the first DC-to-AC converter being configured to output a modulated signal of the voltage measurement signal, the second AC-to-DC converter being configured to output a demodulated signal of the voltage measurement signal; a high-frequency transformer comprising a primary coil connected with an output terminal of the first DC-to-AC converter to receive the modulated signal and a secondary coil connected with an input terminal of the second AC-to-DC converter; and a controller configured to provide control signals to control switching devices of the first DC-to-AC converter to control a turn-on sequence of each switching device such that the first DC-to-AC converter outputs the modulated signal, to calculate signal parameters including phase information and amplitude information of the high voltage on the high-voltage node, and to output the calculated signal parameters.

The present disclosure provides in yet another aspect a method for measuring a high voltage on a high-voltage node using a measuring apparatus, the measuring apparatus including a power electronic converter, a high-frequency transformer and a controller, the power electronic converter including a first AC-to-DC converter, a first DC-to-AC converter and a second AC-to-DC converter, the first AC-to-DC converter being configured to obtain a voltage measurement signal of the high voltage on the high-voltage node, the first DC-to-AC converter being configured to output a modulated signal of the voltage measurement signal, the second AC-to-DC converter being configured to output a demodulated signal of the voltage measurement signal; the high-frequency transformer being coupled between the first DC-to-AC converter and the second AC-to-DC converter to transmit the modulated signal, the method including providing, at the controller, control signals to switching devices of the first DC-to-AC converter to control a turn-on sequence of each switching device such that the first DC-to-AC converter outputs the modulated signal; and the method further including calculating, at the controller, signal parameters of phase information and amplitude information of the high voltage on the high-voltage node, and outputting the calculated signal parameters.

### BRIEF DESCRIPTION OF THE DRAWINGS

The disclosed aspects will hereinafter be described in connection with the appended drawings that are provided to illustrate and not to limit the scope of the disclosure.

FIG. 1 is a schematic block diagram of a system for measuring a high voltage on a high-voltage node according to an example of the disclosure.

FIG. 2 is a schematic block diagram of the measuring apparatus of the system illustrated in FIG. 1 according to an example of the disclosure.

FIG. 3 is a schematic block diagram of the measuring apparatus of the system illustrated in FIG. 1 according to another example of the disclosure.

FIG. 4 shows an exemplary implementation of the measuring apparatus illustrated in FIG. 2.

FIG. 5 shows another exemplary implementation of the measuring apparatus illustrated in FIG. 2.

FIG. 6 shows yet another exemplary implementation of the measuring apparatus illustrated in FIG. 2.

FIG. 7 shows an exemplary implementation of the measuring apparatus illustrated in FIG. 3.

FIG. 8 is a flowchart of a method for measuring a high voltage on a high-voltage node according to an example of the disclosure.

FIGS. 9-11 show exemplary simulation results according to an example of the disclosure.

### DETAILED DESCRIPTION

The present disclosure relates to a solution for measuring a high voltage without the EMU which has caused many problems as described above. The solution of the present disclosure can measure the high voltage with high accuracy and also can provide various signal parameters including phase and amplitude information of the high voltage. In addition, the solution of the present disclosure can avoid Ferro-resonance, reduce cost and volume. Examples of the present disclosure will be described below.

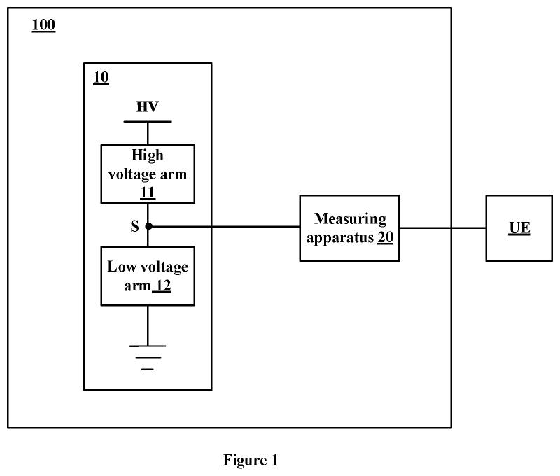

FIG. 1 illustrates a system 100 for measuring a high voltage on a high-voltage node according to an example of the disclosure. The high voltage node HV may carry a DC or AC high voltage. The high voltage may be in a range between approximately from 110 kV to 500 kV.

Referring to FIG. 1, the system 100 mainly includes a high voltage divider 10 and a measuring apparatus 20. The high voltage divider 10 is coupled between the high voltage node HV and the measuring apparatus 20. The measuring apparatus 20 is coupled between the high voltage divider 10 and user equipment UE.

The high voltage divider 10 includes a high voltage arm 11 and a low voltage arm 12 which are connected in series between the high voltage node HV and the ground GND, wherein a sensing node S located between the high voltage arm 11 and the low voltage arm 12 is used to tap a sensing signal, i.e., a voltage measurement signal of the high voltage.

In an example, a voltage dividing ratio of the high voltage divider 10 may be changed by means of changing at least one of the high voltage arm 11 and the low voltage arm 12. In this example, the low voltage arm 12 may be adjusted such that a voltage divided by the low voltage arm 12 is matched with an optimized voltage required by the measuring apparatus 20 for achieving high measurement accuracy, or with a withstand voltage of the measuring apparatus 20 for safety requirements.

The high voltage divider 10 may be implemented as a capacitor voltage divider, a resistor voltage divider or a hybrid divider. In an example of the capacitor voltage divider, the high voltage arm 11 and the low voltage arm 12 are respectively implemented as a voltage-dividing capacitor unit having one or more voltage-dividing capacitors. In an example of the resistor voltage divider, the high voltage arm 11 and the low voltage arm 12 are respectively implemented as a voltage-dividing resistor unit having one or more voltage-dividing resistors. In an example of the hybrid divider, the high voltage arm 11 and the low voltage arm 12 are respectively implemented as a hybrid voltage-dividing unit having voltage-dividing capacitors and resistors.

The measuring apparatus 20 may be accommodated in a terminal box (not shown) and the terminal box is coupled to a terminal of the low voltage arm 12. According to examples of the present disclosure, the measuring apparatus 20 does not need the large magnetic core as well as heavy primary and secondary windings as required by the prior art solution, the volume of the measuring apparatus 20 of is reduced and thus the measuring apparatus 20 can be accommodated in the terminal box without the problem of requiring a large space. In an example, the measuring apparatus 20 provided in the terminal box is coupled with the sensing node S (i.e., a terminal of the low voltage arm 11) via a wire. With this configuration, various types of services can be carried out at user side in a much easier manner.

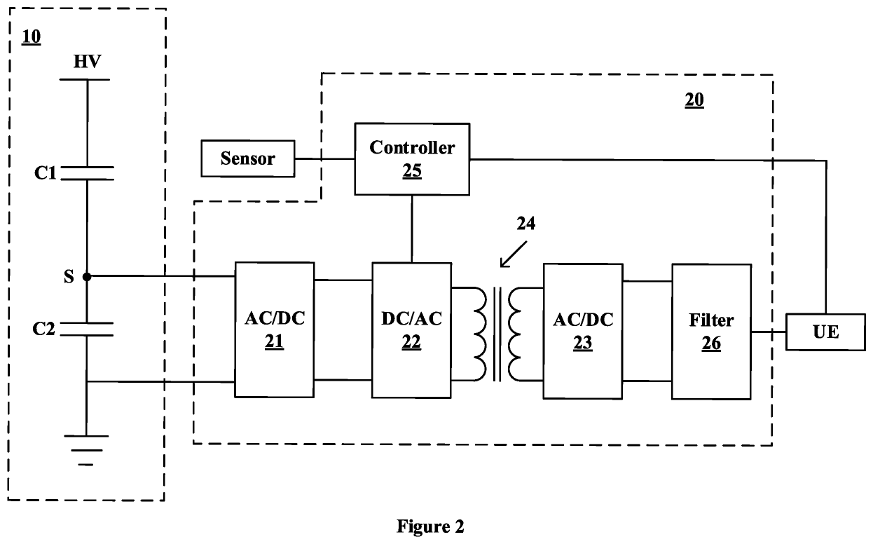

FIG. 2 illustrates an example of the measuring apparatus 20 coupled with a capacitor voltage divider 10 having a voltage-dividing capacitor C1 (served as the high voltage arm 11) and a voltage-dividing capacitor C2 (served as the low voltage arm 12).

Referring to FIG. 2, the measuring apparatus 20 comprises a power electronic converter, a high-frequency transformer 24 and a controller 25. The power electronic converter comprises a first AC-to-DC converter 21, a first DC-to-AC converter 22, a second AC-to-DC converter 23 and a filter 26. Connection relationships and working principles of those elements of the measuring apparatus 20 will be described below.

Continuing with reference to FIG. 2, two input terminals of the first AC-to-DC converter 21 are connected with two terminals of the voltage-dividing capacitor C2 respectively to obtain a voltage measurement signal of the high voltage. The voltage measurement signal is converted from an AC signal to a DC signal by the first AC-to-DC converter 21. Output terminals of the first AC-to-DC converter 21 are connected with input terminals of first DC-to-AC converter 22. The first DC-to-AC converter 22 includes a plurality of switching devices that may be implemented with power electronics switching devices such as MOSFETs or IGBTs. Each switching device has a control end to receive a control signal for controlling a turn-on sequence of the switching device such that the first DC-to-AC converter 22 outputs a modulated signal. For example, the tap voltage across the capacitor C2 is fed to a modulating unit including the first AC-to-DC converter 21 and the first DC-to-AC converter 22 and modulated to a high-frequency PWM signal. The frequency of the PWM signal may be higher than 20 kHz, or even higher than 50 kHz.

The high-frequency transformer 24 comprises a primary coil and a secondary coil. In an example, a turns-ratio of the primary coil and the secondary coil is between 1 and 10. The primary coil is connected with an output terminal of the first DC-to-AC converter 22 to receive the modulated signal which is isolated and further stepped down to a low voltage of 100V or 100/\sqrt{3} V by the high-frequency transformer 24. The secondary coil is connected with an input terminal of the second AC-to-DC converter 23. The modulated signal which has been further stepped down is demodulated by a demodulating unit including the second AC-to-DC converter 23 and the filter 26. The second AC-to-DC converter 23 outputs the demodulated signal to user-side devices such as meters and protective relays.

In an example, the filter 26 is coupled with the output terminal of the second AC-to-DC converter 23. The filter 26 is used for filtering out high frequency components of the demodulated signal before the demodulated signal is output to the user-side devices.

The controller 25 includes an input end, an output end and a control end. The controller 25 receives sensor information from sensors associated with both the high voltage divider 10 and the measuring apparatus 20 via the input end. The controller provides a control signal for controlling a turn-on sequence of each switching device of the first DC-to-AC converter 22 via the control end. The controller 25 calculates signal parameters including phase information and amplitude information of the high voltage on the high-voltage node based on the sensor information and outputs the calculated signal parameters to user-side devices such DSP, MCU and ASIC via the output end.

The associated sensors may include a voltage sensor for measuring a voltage Vₜ across the voltage dividing capacitor C2, a current sensor for measuring a current Iₜ through a circuit branch connecting the sensing node S and an input terminal of the first AC-to-DC converter 21, and temperature sensors for measuring a temperature of the voltage dividing capacitor C2 and an ambient temperature around the measuring apparatus 20 (e.g., a temperature of an inner space of the terminal box).

The sensor information may include parameters measured by the sensors and parameters derived from the measured parameters. For example, the sensor information includes the voltage Vₜ across the low-voltage dividing capacitor C2 measured by the voltage sensor, the current Iₜ through the circuit branch connecting the sensing node S and an input terminal of the first AC-to-DC converter 21 measured by the current sensor, the temperature of the low-voltage dividing capacitor C2 measured by a temperature probe and an ambient temperature around the measuring apparatus 20 measured by an ambient temperature sensor. The sensor information may also include parameters that are calculated based on the measured parameters. The calculation may be performed in a processor integrated with the sensor or in a processor integrated with the controller. For example, the sensor information may include an angular frequency of the tap voltage signal, an impedance of the measuring apparatus 20 and temperature shifts of devices of the measuring apparatus 20. The method for calculating those parameters is not limited in the present disclosure.

In an example, the calculated signal parameters may include at least one of a voltage magnitude peak value, an RMS value, a polarity, a phase value, a harmonic value and a wave-shape of the high voltage. The signal parameters may also include a phase offset between a phase of the high voltage signal and that of the voltage measurement signal. The signal parameters may also include an amplitude deviation between amplitude of the high voltage signal and that of the voltage measurement signal.

It is advantageous to provide the signal parameters because the quality of electrical power from the high voltage node can be measured based on those signal parameters. Further, power quality issues (e.g., sags/swells, harmonic distortion and inter harmonics, spikes/transients, under-voltage/over-voltage) which may impact the operation and efficiency of electrical equipment can be detected timely. As a result, power quality solutions that maximize operational continuity and ensure a smooth and continuous power supply in industrial applications can be offered. In addition, protection, load control and metering can also be realized based on the signal parameters. For example, a protecting system uses the signal parameters for continuously scanning for faults, which enables quickly disconnect fault section from grid. For example, the signal parameters are needed for revenue metering and energy metering.

In an example, the controller 25 calculates the phase offset based on the following formula (1):

$$Δ P = {k}_{1} * ( Δ {P}_{C} + Δ {P}_{R} ) + {k}_{2} * ( Δ {P}_{L} + Δ {P}_{S} ) \qquad ( 1 )$$

where “ΔP” is the phase offset, “ΔP_{C}” is a sub-offset caused by the capacitance of the voltage-dividing capacitor unit, “ΔP_{R}” is a sub-offset caused by the impedance of the measuring apparatus 20, “ΔP_{L}” is a sub-offset caused by the leakage inductance of the measuring apparatus 20, “ΔP_{S}” is a sub-offset caused by the parasitic capacitance of the measuring apparatus 20, “k₁” and “k₂” are weights, a sum of “k₁” and “k₂” is equal to 1, a range of “k₁” is between 0.95 and 0.99, and a range of “k₂” is between 0.01 and 0.05.

In an example, the controller 25 calculates the amplitude deviation based on the following formula (2):

$$Δ a = {f}_{1} * ( Δ {a}_{C} + Δ {a}_{R} ) + {f}_{2} * Δ {a}_{D} \qquad ( 2 )$$

where “Δa” is the amplitude deviation, “Δa_{C}” is a sub-deviation caused by the capacitance of the voltage-dividing capacitor unit, “Δa_{R}” is a sub-deviation caused by the impedance of the measuring apparatus, “Δa_{D}” is a sub-deviation caused by the drop voltage of the measuring apparatus 20, “f₁” and “f₂” are weights, a sum of “f₁” and “f₂” is equal to 1, a range of “f₁” is between 0.9 and 0.95, and a range of “f₂” is between 0.05 and 0.1.

In addition, the measured/calculated signals can be compensated in the controller. For example, the measured voltage is compensated by means of modifying the PWM signals. The measurement signal with compensation can also achieve high accuracy level, e.g., measurement accuracy on harmonics can be up to 60th order.

An example of the disclosure may include a pre-calibration process, such as curve fitting and/or look-up table, for dynamically adjusting the PWM control signals to adapt subtle to drifting due to ambient condition changes (e.g., changes in ambient temperature). In this way, the measurement accuracy can be further improved.

The controller 25 may be implemented by means of hardware or software or a combination of hardware and software, including a non-transitory computer readable medium stored in a memory and implemented as instructions executed by a processor. Regarding the part implemented by means of hardware, it may be implemented in application-specific integrated circuit (ASIC), digital signal processor (DSP), data signal processing device (DSPD), programmable logic device (PLD), field programmable gate array (FPGA), processor, controller, microcontroller, microprocessor, electronic unit, or a combination thereof. The part implemented by software may include microcode, program code or code segments. The software may be stored in a machine-readable storage medium, such as a memory.

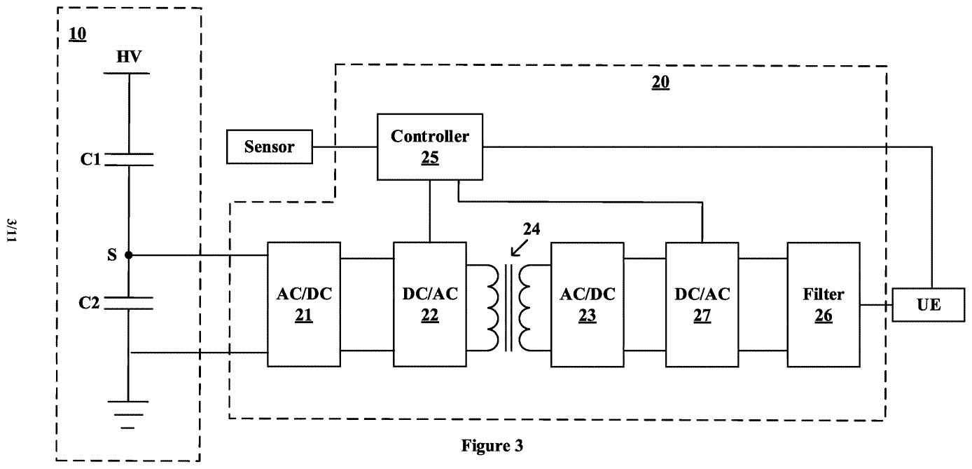

FIG. 3 illustrates another example of the measuring apparatus 20. The example of FIG. 3 is different from the example of FIG. 2 in that it further includes a second DC-to-AC converter 27 coupled between the second AC-to-DC converter 23 and the filter 26. The second DC-to-AC converter 27 may be implemented in a manner similar to that of the first DC-to-AC converter 22. For example, the second DC-to-AC converter 27 includes a plurality of switching devices that may be implemented with power electronics switching devices such as MOSFETs or IGBTs. Each switching device has a control end to receive a control signal for controlling a turn-on sequence of the switching device from the controller 25. The wave-form of the high voltage is restored by the second DC-to-AC converter 27 and the second DC-to-AC converter 27 outputs an analog AC signal including phase information and amplitude information of the high voltage. A frequency of the output analog signal is about 50 Hz. In addition, the phase information and amplitude information can also be output from the controller 25 in the example of FIG. 3.

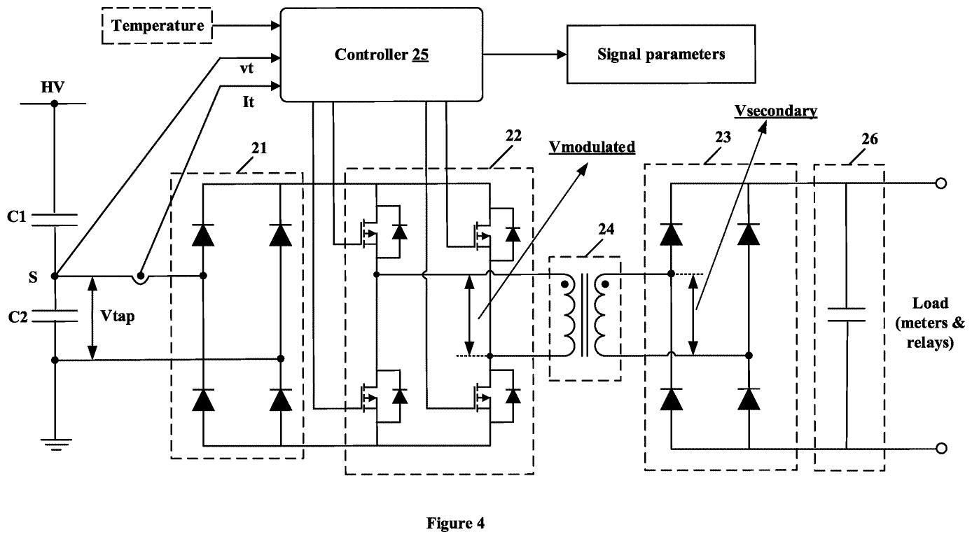

In the example of FIG. 3, the phase information and amplitude information may be provided with the digital signal output from the controller 25 (as shown in FIG. 2) and/or with the analogue signal output from the second DC-to-AC converter 27 (as shown in FIG. 3). Exemplary implementations of the measuring apparatus 20 will be described with reference to FIGS. 4-6.

FIG. 4 shows an exemplary implementation of the measuring apparatus 20 illustrated in FIG. 2. Referring to FIG. 4, the high voltage side AC-to-DC converter 21 (i.e., the first AC-to-DC converter 21) is composed of a rectifier comprising two diode half-bridges. The primary side DC-to-AC convertor 22 (i.e., the first DC-to-AC convertor 22) is a full-bridge converter comprising two half-bridges of series-connected switching devices. The switching devices are controlled by the controller 25 as described above. The secondary side AC- to DC convertor 23 (i.e., the second AC-to-DC converter 23) is composed of a rectifier comprising two diode half-bridges, similar to that of the AC-to-DC converter 21. The filer 26 comprises a capacitor for filtering out high frequency components of the demodulated signal.

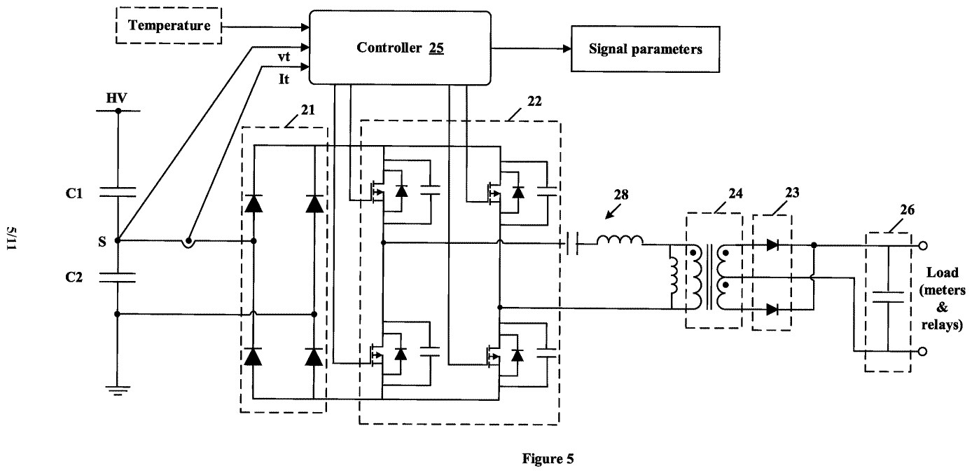

FIG. 5 shows another exemplary implementation of the measuring apparatus 20 illustrated in FIG. 2. The example of FIG. 5 is different from the example of FIG. 4 in that it further comprises a resonant LLC circuit 28 coupled between the output terminal of the first DC-to-AC convertor 22 and the primary side of the high-frequency transformer 24. Moreover, the secondary side AC-to-DC converter 23 is implemented with a different topology. For example, the secondary side DC-to-AC converter 23 comprises a diode bridge rectifier and optionally a filter.

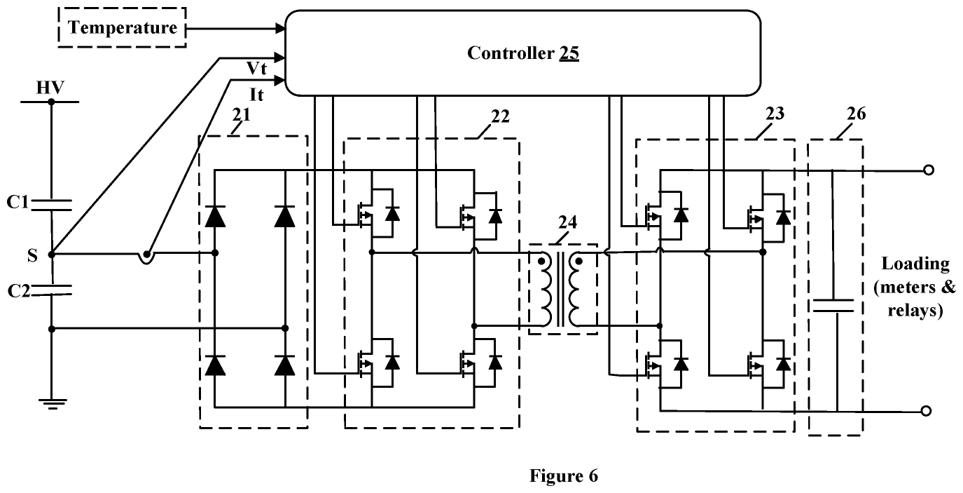

FIG. 6 shows yet another exemplary implementation of the measuring apparatus 20 illustrated in FIG. 2. The example of FIG. 6 is different from the example of FIG. 4 in that the secondary side AC-DC converter 23 (i.e., the second AC-DC converter 23) is implemented with a controlled H-bridge circuit, which includes four switching devices interconnected as the H-bridge circuit. The switching devices can be provided as power MOSFETs, IGBTs, IGCTs and the like, each having a free-wheeling diode, respectively, in parallel. The turn-on sequence of each switching device is controlled by the controller 25 (e.g., the controller 25 provides a control signal to a control end of each switching device of the converter 23).

In the example of FIG. 6, voltage adjustment and compensation to the voltage measurement signal may be performed at the secondary side. For example, the controller 25 adjusts controlling signals provided to the secondary side converter 23 such that the amplitude of the voltage measurement signal is adjusted. In an example, the controller 25 adjusts the controlling signals provided to the switching devices of the secondary side converter 23 such that the amplitude of the voltage measurement signal is adjusted.

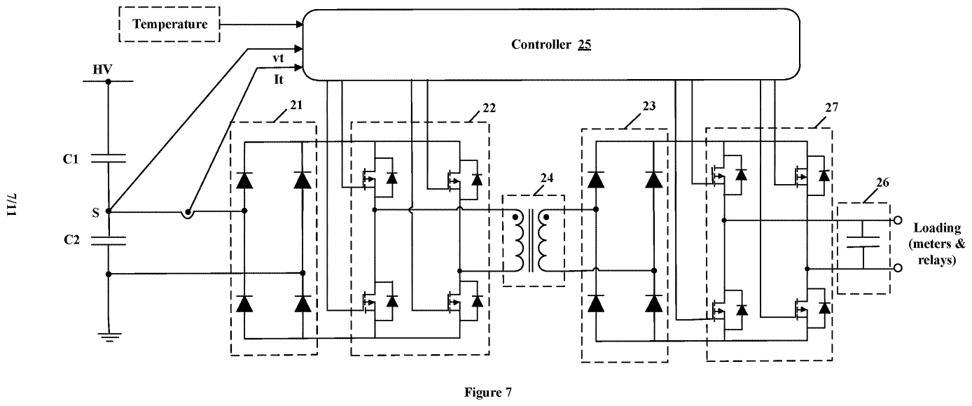

FIG. 7 shows an exemplary implementation of the measuring apparatus 20 illustrated in FIG. 3. The example of FIG. 6 is different from the example of FIG. 4 in that it further comprises a secondary side DC-to-AC converter 27 (i.e., the second DC-to-AC converter 27) which is a full-bridge converter comprising two half-bridges of series-connected switching devices controlled by the controller 25. The second DC-to-AC converter 27, implemented in a manner similar to that of the first DC-to-AC converter 22, is a full-bridge converter comprising two half-bridges of series-connected switching devices. The turn-on sequence of each switching device is controlled by the controller 25.

It is noted that the circuits of the measuring apparatus 20 may have different topologies, which are not limited by the examples described above. For example, a push-pull circuit is also feasible. Another aspect of the disclosure, a method for measuring a high voltage on a high-voltage node, will be described below.

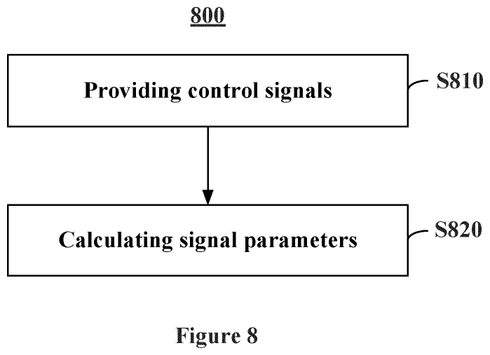

FIG. 8 illustrates a flowchart of a method 800 for measuring a high voltage on a high-voltage node using a measuring apparatus. The measuring apparatus may be the measuring apparatus 20 of the present disclosure and thus various features described above with reference to the measuring apparatus 20 are also applicable to the method 800. The method 800 includes the controlling and calculating performed by the controller 25.

With reference to FIG. 8, in step S810, control signals are provided to switching devices of the first DC-to-AC converter to control a turn-on sequence of each switching device such that the first DC-to-AC converter outputs a modulated signal, such as a high-frequency PWM signal.

In step S820, signal parameters including phase information and amplitude information of the high voltage are calculated, and the calculated signal parameters are output. In an example, the calculated signal parameters include: at least one of a voltage magnitude peak value, an RMS value, a polarity, a phase value, a harmonic value and a wave-shape of the high voltage signal; a phase offset between a phase of the high voltage signal and a phase of the voltage measurement signal; and an amplitude deviation between an amplitude of the high voltage signal and an amplitude of the voltage measurement signal.

According to examples of the present disclosure, by replacing the EMU with the power electronic converters and the high-frequency transformer, the transient response is improved and the Ferro-resonance is avoided. Various signal detection such a harmonic detection is available according to examples of the present disclosure. Cost and volume reduction can be achieved without the intermediate voltage transformer (IVT). The accuracy level of measuring the high voltage can achieve 0.1% with the improved transient response. In addition, a lower tap voltage is required, which not only decreases insulation requirements of mono-bushing and isolation requirements of the HFT, but also brings down the withstand voltage of power electronic device and thus the cost.

Exemplary simulation results will be described with reference to FIGS. 8 to 10, which show exemplary simulation results on the topology presented in FIG. 4.

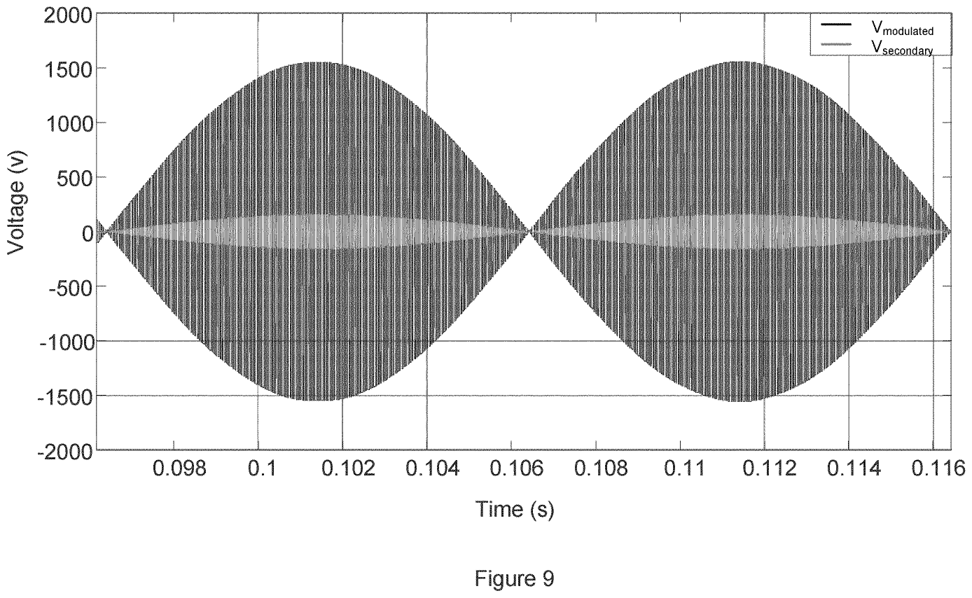

In FIGS. 9-11, the vertical axis represents voltage and the horizontal axis represents time. The topology is simulated in MATLAB or Simulink. In FIGS. 9 to 11, “Vₜₐₚ” represents the tap voltage across the voltage-dividing capacitor C2, “V_{modulate}” represents the modulated voltage at the primary side, “V_{secondary}” represents the voltage at the secondary side, and “V_{syn}” represents a synthesized voltage based on the measured voltage and the polarity of the tap voltage. In the simulations, the high voltage is set to 110 kV, and the tap voltage from the capacitor divider is set to 1 kV. The modulation frequency of the DC-to-AC converter at the primary side is set to 20 KHz. In this manner, the rectified tap voltage is modulated to a 20 kHz PWM-based signal and then transmitted by the high frequency transformer with a turns-ratio of 10.

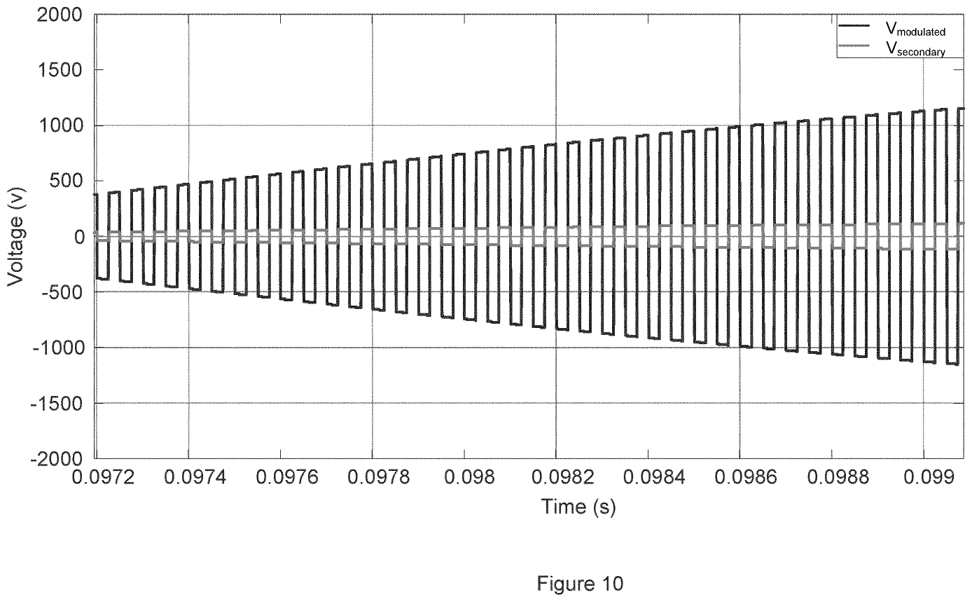

FIG. 9 shows the modulated voltage V_{modulate} represented by the black curve and the secondary-side voltage V_{secondary} represented by the grey curve in one cycle (e.g., 0.02 s). FIG. 10 is a view enlarging a portion of FIG. 9 and an enlarged view of a comparison of the modulated voltage V_{modulate} and the secondary voltage V_{secondary} can be clearly seen in FIG. 9, where the frequency of the PWM pulses voltage signal is set to 20 kHz at the primary side and secondary side of the HFT and the voltage ratio is set to 10.

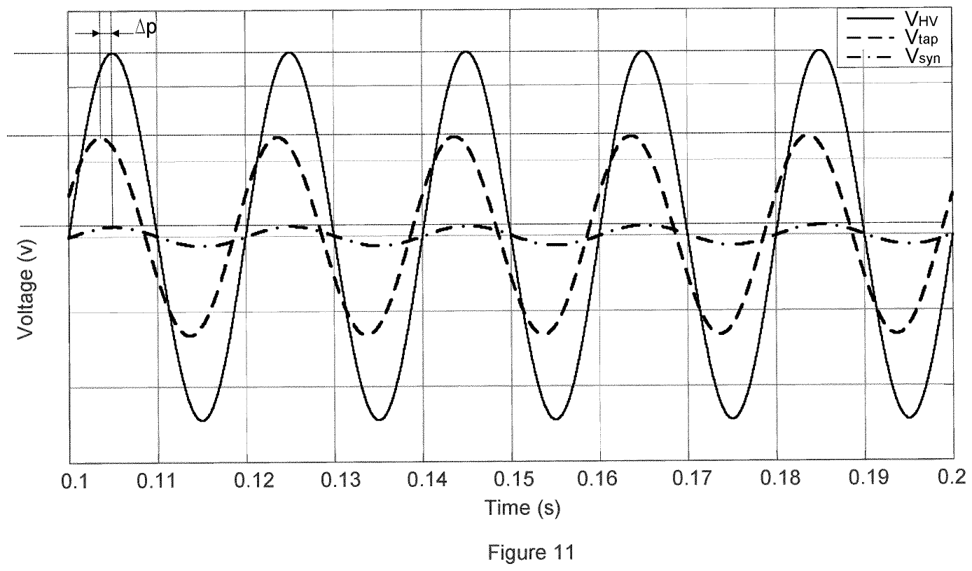

FIG. 11 shows the high voltage V_{HV} represented by the solid line, the tap voltage Vₜₐₚ represent by the dashed line and the synthesized voltage V_{syn} represent by the dash-dotted line. The polarity of the tap voltage is obtained to restore a complete wave-shape of the high voltage. For example, zero-crossing detection or PLL is used to obtain the polarity.

The phase offset ΔP between the high voltage and the measured voltage can be calculated and the synthesized voltage can be compensated based on the phase offset ΔP. The amplitude deviation (not shown) between the high voltage and the measured voltage also can be calculated and the synthesized voltage can be compensated based on the amplitude deviation. In this way, the phase and amplitude information of the high voltage can be output by the apparatus of the present disclosure.

Software should be considered broadly to represent instructions, instruction sets, code, code segments, program code, programs, subroutines, software modules, applications, software applications, software packages, routines, subroutines, objects, running threads, processes, functions, and the like. Software can reside on a non-transitory computer readable medium. Such non-transitory computer readable medium may include, for example, a memory, which may be, for example, a magnetic storage device (e.g., a hard disk, a floppy disk, a magnetic strip), an optical disk, a smart card, a flash memory device, a random-access memory (RAM), a read only memory (ROM), a programmable ROM (PROM), an erasable PROM (EPROM), an electrically erasable PROM (EEPROM), a register, or a removable disk. Although a memory is shown as being separate from the processor in various aspects presented in this disclosure, a memory may also be internal to the processor (e.g., a cache or a register).

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein. All structural and functional equivalent transformations to the elements of the various aspects of the disclosure, which are known or to be apparent to those skilled in the art, are intended to be covered by the claims.

1. An apparatus for measuring a high voltage signal on a high-voltage node, comprising:
a power electronic converter comprising a first AC-to-DC converter, a first DC-to-AC converter and a second AC-to-DC converter, the first AC-to-DC converter being connected with a low voltage arm of a high voltage divider, which is coupled between the high-voltage node and the apparatus, to obtain a voltage measurement signal, the first DC-to-AC converter being configured to output a modulated signal of the voltage measurement signal, the second AC-to-DC converter being configured to output a demodulated signal of the voltage measurement signal;
a high-frequency transformer comprising a primary coil connected with an output terminal of the first DC-to-AC converter to receive the modulated signal and a secondary coil connected with an input terminal of the second AC-to-DC converter; and
a controller configured to provide control signals to switching devices of the first DC-to-AC converter to control a turn-on sequence of each switching device such that the first DC-to-AC converter outputs the modulated signal, to calculate signal parameters including phase information and amplitude information of the high voltage on the high-voltage node, and to output the calculated signal parameters.

2. The apparatus of claim 1, wherein the signal parameters include:
at least one of a voltage magnitude peak value, an RMS value, a polarity, a phase value, a harmonic value and a wave-shape of the high voltage signal;
a phase offset between a phase of the high voltage signal and that of the voltage measurement signal; and
an amplitude deviation between an amplitude of the high voltage signal and that of the voltage measurement signal.

3. The apparatus of claim 1, wherein the apparatus further comprises a second DC-to-AC converter, an input terminal of the second DC-to-AC converter being connected with an output terminal of the second AC-to-DC converter, and the second DC-to-AC converter being configured to output an analog AC signal including phase information and amplitude information of the high voltage signal on the high-voltage node.

4. The apparatus of claim 1, wherein the controller is configured to calculate the signal parameters based on sensor information received via its input end, the sensor information including a voltage across the low voltage arm and a current through a circuit branch connecting the high voltage divider and the apparatus.

5. The apparatus of claim 2, wherein the high voltage divider is a capacitor voltage divider and the low voltage arm is a voltage-dividing capacitor unit having one terminal connected to ground.

6. The apparatus of claim 5, wherein the controller is configured to calculate the phase offset based on the following formula:
$$Δ P = {k}_{1} * ( Δ {P}_{C} + Δ {P}_{R} ) + {k}_{2} * ( Δ {P}_{L} + Δ {P}_{S} )$$
where “ΔP” is the phase offset;
“ΔP_{C}” is a sub-offset caused by the capacitance of the voltage-dividing capacitor unit;
“ΔP_{R}” is a sub-offset caused by an impedance of the apparatus;
“ΔP_{L}” is a sub-offset caused by a leakage inductance of the apparatus;
“ΔP_{S}” is a sub-offset caused by a parasitic capacitance of the apparatus;
“k₁” and “k₂” are weights, a sum of “k₁” and “k₂” is equal to 1, a range of “k₁” is between 0.95 and 0.99, and a range of “k₂” is between 0.01 and 0.05.

7. The apparatus of claim 5, wherein the controller is configured to calculate the amplitude deviation based on the following formula:
$$Δ a = {f}_{1} * ( Δ {a}_{C} + Δ {a}_{R} ) + {f}_{2} * Δ {a}_{D}$$
where “Δa” is the amplitude deviation;
“Δa_{C}” is a sub-deviation caused by the capacitance of the voltage-dividing capacitor unit;
“Δa_{R}” is a sub-deviation caused by an impedance of the apparatus;
“Δa_{D}” is a sub-deviation caused by a drop voltage of the apparatus;
“f₁” and “f₂” are weights, a sum of “f₁” and “f₂” is equal to 1, a range of “f₁” is between 0.9 and 0.95, and a range of “f₂” is between 0.05 and 0.1.

8. The apparatus of claim 1, wherein a turns-ratio of the primary coil and the secondary coil is between 1 and 10.

9. The apparatus of claim 1, wherein the apparatus further comprises a filter for filtering out high frequency components of the demodulated signal before the demodulated signal is output.

10. The apparatus of claim 1, wherein the apparatus is provided within a terminal box which is coupled to a terminal of the low voltage arm.

11. A system for measuring a high voltage signal on a high-voltage node, comprising:
a high voltage divider connected with the high-voltage node, the high voltage divider comprising a high voltage arm and a low voltage arm; and
a measuring apparatus provided in a terminal box coupled with the high voltage divider, the measuring apparatus comprising:
a power electronic converter comprising a first AC-to-DC converter, a first DC-to-AC converter and a second AC-to-DC converter, the first AC-to-DC converter being connected with the low voltage arm to obtain a voltage measurement signal, the first DC-to-AC converter being configured to output a modulated signal of the voltage measurement signal, the second AC-to-DC converter being configured to output a demodulated signal of the voltage measurement signal;
a high-frequency transformer comprising a primary coil connected with an output terminal of the first DC-to-AC converter to receive the modulated signal and a secondary coil connected with an input terminal of the second AC-to-DC converter; and
a controller configured to provide control signals to control switching devices of the first DC-to-AC converter to control a turn-on sequence of each switching device such that the first DC-to-AC converter outputs the modulated signal, to calculate signal parameters including phase information and amplitude information of the high voltage on the high-voltage node, and to output the calculated signal parameters.

12. The system of claim 11, wherein at least one of the high voltage arm and the low voltage arm are adjusted such that a voltage divided by the low voltage arm is matched with an optimized voltage required by the power electronic converter or with a withstand voltage of the power electronic converter.

13. The system of claim 11, wherein the high voltage divider is a capacitor voltage divider and the low voltage arm is a voltage-dividing capacitor unit comprising one or more capacitors.

14. The system of claim 13, wherein the voltage-dividing capacitor unit has one terminal connected to ground and another terminal connected to another voltage-dividing capacitor unit of the capacitor voltage divider, and the another terminal of the voltage-dividing capacitor unit is coupled to an input terminal of the first AC-to-DC converter via a wire.

15. A method for measuring a high voltage signal on a high-voltage node using a measuring apparatus,
the measuring apparatus comprising a power electronic converter, a high-frequency transformer and a controller,
the power electronic converter comprising a first AC-to-DC converter, a first DC-to-AC converter and a second AC-to-DC converter, the first AC-to-DC converter being configured to obtain a voltage measurement signal of the high voltage on the high-voltage node, the first DC-to-AC converter being configured to output a modulated signal of the voltage measurement signal, the second AC-to-DC converter being configured to output a demodulated signal of the voltage measurement signal;
the high-frequency transformer being coupled between the first DC-to-AC converter and the second AC-to-DC converter to transmit the modulated signal;
the method comprising providing, at the controller, control signals to switching devices of the first DC-to-AC converter to control a turn-on sequence of each switching device such that the first DC-to-AC converter outputs the modulated signal; and
the method further comprising calculating, at the controller, signal parameters of phase information and amplitude information of the high voltage on the high-voltage node, and outputting the calculated signal parameters.

16. The apparatus of claim 4, wherein the sensor information further includes a temperature of the low voltage arm and temperature shifts of devices of the power electronic converter.

17. The system of claim 11, wherein the signal parameters include:
at least one of a voltage magnitude peak value, an RMS value, a polarity, a phase value, a harmonic value and a wave-shape of the high voltage signal;
a phase offset between a phase of the high voltage signal and that of the voltage measurement signal; and
an amplitude deviation between an amplitude of the high voltage signal and that of the voltage measurement signal.

18. The system of claim 11, wherein the high voltage divider is a capacitor voltage divider and the low voltage arm is a voltage-dividing capacitor unit having one terminal connected to ground.

19. The system of claim 11, wherein the apparatus further comprises a second DC-to-AC converter, an input terminal of the second DC-to-AC converter being connected with an output terminal of the second AC-to-DC converter, and the second DC-to-AC converter being configured to output an analog AC signal including phase information and amplitude information of the high voltage signal on the high-voltage node.

20. The system of claim 11, wherein the controller is configured to calculate the signal parameters based on sensor information received via its input end, the sensor information including a voltage across the low voltage arm and a current through a circuit branch connecting the high voltage divider and the apparatus.
